(19) United States
(12) Patent Application Publication
(10) Pub. No.: US 2009/0238002 A1
(43) Pub. Date: Sep. 24, 2009

(54) NAND TYPE NON-VOLATILE MEMORY AND OPERATING METHOD THEREOF

(75) Inventors: Wei-Zhe Wong, Tainan City (TW); Chih-Wei Hung, Hsin-chu City (TW); Cheng-Wei Chen, Hualien County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 12/053,636

(22) Filed: Mar. 24, 2008

(51) Int. Cl. G11C 16/12; G11C 16/04

(52) U.S. Cl. 365/185.17; 365/185.28

(57) ABSTRACT

A NAND type non-volatile memory having a plurality of bit lines and a dummy bit line is provided. The intersections of each of the bit lines with a first select gate line, a plurality of word lines, and a second select gate line are corresponding to a memory cell row. The intersections of the dummy bit line with the first select gate line, the word lines, and the second select gate line are corresponding to a dummy memory cell row. A source line is disposed on the substrate at one side of the memory cell rows, wherein the dummy memory cell row and the dummy bit line are served as a current path for connecting the source line.

### BACKGROUND OF THE INVENTION

1. Field of the Invention

The present invention generally relates to a semiconductor memory device, in particular, to a NAND type non-volatile memory and a fabricating method thereof.

2. Description of Related Art

Non-volatile memory device is broadly applied in personal computers and other electronic apparatuses since it is able to write, read, or erase data repeatedly and the data stored in the memory can be kept even after the power supply is cut off.

A typical non-volatile memory device is usually designed to have a stacked-gate structure including a floating gate and a control gate made of doped polysilicon. The floating gate is disposed between the control gate and a substrate and is floated, namely, not connected to any circuit. The control gate is connected to a word line. Besides, the non-volatile memory further includes a tunneling oxide layer and an inter-gate dielectric layer respectively located between the substrate and the floating gate and between the floating gate and the control gate.

On the other hand, the most commonly-adopted non-volatile memory array structures include a NOR type array structure and a NAND type array structure. In a NAND type non-volatile memory, memory cells are connected to each other in series so that the integration and space efficiency of the NAND type non-volatile memory are both better than those of a NOR type non-volatile memory. Thereby, NAND type non-volatile memory has been broadly applied in various electronic products.

Generally speaking, when a reading operation is performed to the memory cells in a NAND type non-volatile memory, the reading current is passed through the same row of memory cells and converged at a source line to read the data. Besides, a source line plug is further disposed above the source line. The source line plug is connected to at least three dummy bit lines and is connected to an external circuit through the three dummy bit lines. Because the source line plug takes up at least part of the surface area of the (at least three) bit lines, the integration of the device is reduced and which is disadvantageous to device minimization.

### SUMMARY OF THE INVENTION

Accordingly, the present invention is directed to a NAND type non-volatile memory and an operating method thereof, wherein no source line plug is disposed so that the surface area of the NAND type non-volatile memory is reduced and the device integration thereof is improved.

The present invention is directed to a NAND type non-volatile memory and an operating method thereof, wherein no source line plug is disposed so that the fabrication process is simplified and the fabrication cost is reduced.

The present invention provides a NAND type non-volatile memory including a plurality of memory cell arrays, wherein each of the memory cell arrays includes a first select gate line, a plurality of word lines, a second select gate line, a plurality of bit lines, a dummy bit line, a plurality of drain regions, a plurality of source regions, and a source line. The first select gate line, the word lines, and the second select gate line are disposed in parallel on the substrate and extended toward a first direction. The bit lines and the dummy bit line are disposed in parallel on the substrate and extended toward a second direction, wherein the second direction intersects the first direction. The intersections of each of the bit lines with the first select gate line, the word lines, and the second select gate line are corresponding to a memory cell row, and the intersections of the dummy bit line with the first select gate line, the word lines, and the second select gate line are corresponding to a dummy memory cell row. The drain regions are respectively disposed in the substrate at a first side of the memory cell rows and the dummy memory cell row, and the drain regions are electrically connected to the bit lines and the dummy bit line respectively. The source regions are respectively disposed in the substrate at a second side of the memory cell rows and the dummy memory cell row. The source line is disposed on the substrate at the second side of the memory cell rows and extended toward the second direction, and the source line is electrically connected to the source regions, wherein the dummy memory cell row and the dummy bit line are served as a current path for connecting the source line.

According to an embodiment of the present invention, the intersection of each of the bit lines and each of the word lines is corresponding to a memory cell.

According to an embodiment of the present invention, the intersections of each of the bit lines with the first select gate line and the second select gate line are respectively corresponding to a select unit.

According to an embodiment of the present invention, the memory cell arrays are disposed in mirror symmetry along the second direction, and adjacent two memory cell arrays share the drain regions or the source regions.

The present invention provides an operating method for a NAND type non-volatile memory, wherein the operating method is suitable for a memory cell array. The memory cell array includes a first select gate line, a plurality of word lines, a second select gate line, a plurality of bit lines, a dummy bit line, a plurality of drain regions, a plurality of source regions, and a source line. The first select gate line, the word lines, and the second select gate line are disposed in parallel on the substrate and extended toward a first direction. The bit lines and the dummy bit line are disposed in parallel on the substrate and extended toward a second direction, wherein the second direction intersects the first direction. The intersections of each of the bit lines with the first select gate line, the word lines, and the second select gate line are corresponding to a memory cell row, and the intersections of the dummy bit line with the first select gate line, the word lines, and the second select gate line are corresponding to a dummy memory cell row. The drain regions are respectively disposed in the substrate at a first side of the memory cell rows and the dummy memory cell row, and the drain regions are electrically connected to the bit lines and the dummy bit line respectively. The source regions are respectively disposed in the substrate at a second side of the memory cell rows and the dummy memory cell row. The source line is disposed on the substrate at the second side of the memory cell rows and extended toward the second direction, and the source line is electrically connected to the source regions, wherein the dummy memory cell row and the dummy bit line are served as a current path for connecting the source line. The intersection of each of the bit lines and each of the word lines is corresponding to a memory cell, the intersection of each of the bit lines and the first select gate line is corresponding to a first select unit, and the intersection of each of the bit lines and the second select gate line is corresponding to a second select unit. The operating method of the NAND type non-volatile memory includes following steps.

While programming a selected memory cell in a selected memory cell row, a first voltage is applied to the bit line coupled to the selected memory cell, a second voltage is applied to the non-selected bit lines and the dummy bit line, a third voltage is applied to the first select gate line, a fourth voltage is applied to the word line coupled to the selected memory cell, a fifth voltage is applied to the non-selected word lines, and a sixth voltage is applied to the second select gate line, so as to program the selected memory cell through the channel F-N tunneling effect, wherein the voltage difference between the fourth voltage and the first voltage may incur the F-N tunneling effect, the third voltage is higher than or equal to the threshold voltage of the first select unit, the second voltage prohibits the first select units of the non-selected memory cell rows from being turned on, the fifth voltage is higher than or equal to the threshold voltage of the memory cell, and the sixth voltage is lower than the threshold voltage of the second select unit.

According to an embodiment of the present invention, the first voltage is about 0V, the second voltage is about 2.4V, the third voltage is about 2.4V, the fourth voltage is about 26V, the fifth voltage is about 10V, and the sixth voltage is about 0V.

While reading a selected memory cell in a selected memory cell row, a seventh voltage is applied to the bit line coupled to the selected memory cell, an eighth voltage is applied to the first select gate line, a ninth voltage is applied to the second select gate line, a tenth voltage is applied to the word line coupled to the selected memory cell, and an eleventh voltage is applied to the non-selected word lines, so as to read the selected memory cell, wherein the eighth voltage is higher than or equal to the threshold voltage of the first select unit, the ninth voltage is higher than or equal to the threshold voltage of the second select unit, the eleventh voltage is higher than or equal to the threshold voltage of the memory cell, and the source line is grounded through the dummy memory cell row and the dummy bit line.

According to an embodiment of the present invention, the seventh voltage is about 1.2V, the eighth voltage is about 5V, the ninth voltage is about 5V, the tenth voltage is about 0V, and the eleventh voltage is about 6.5V.

While erasing the memory cells, a twelfth voltage is applied to all of the word lines and a thirteenth voltage is applied to the substrate, so as to erase the memory cells through the channel F-N tunneling effect, wherein the voltage difference between the twelfth voltage and the thirteenth voltage may incur the F-N tunneling effect.

According to an embodiment of the present invention, the twelfth voltage is about 0V, and the thirteenth voltage is about 24V.

In a NAND type non-volatile memory provided by the present invention, a dummy memory cell row and a dummy bit line are directly served as a current path for connecting a source line. Accordingly, no additional fabrication process is required for fabricating the source line plug and the memory array has a regular pattern. As a result, the process window of photolithography and etching process is improved.

In a NAND type non-volatile memory provided by the present invention, only the space of a dummy bit line served as a current path for connecting the source line is used. Accordingly, the surface area of the NAND type non-volatile memory is reduced and the device integration thereof is improved.

In the operation of a NAND type non-volatile memory provided by the present invention, the select unit in the dummy memory cell row can be used as a circuit for controlling the source line. Accordingly, no additionally circuit for controlling the source line is required. As a result, the surface area of the NAND type non-volatile memory is reduced and the device integration thereof is improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic circuit diagram of a NAND type non-volatile memory according to an embodiment of the present invention.

FIG. 1B is a cross-sectional view of a NAND type non-volatile memory according to an embodiment of the present invention.

FIG. 2A is a diagram illustrating a programming operation performed to a memory array.

FIG. 2B is a diagram illustrating a reading operation performed to a memory array.

FIG. 2C is a diagram illustrating an erasing operation performed to all the memory cells in a NAND type non-volatile memory.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

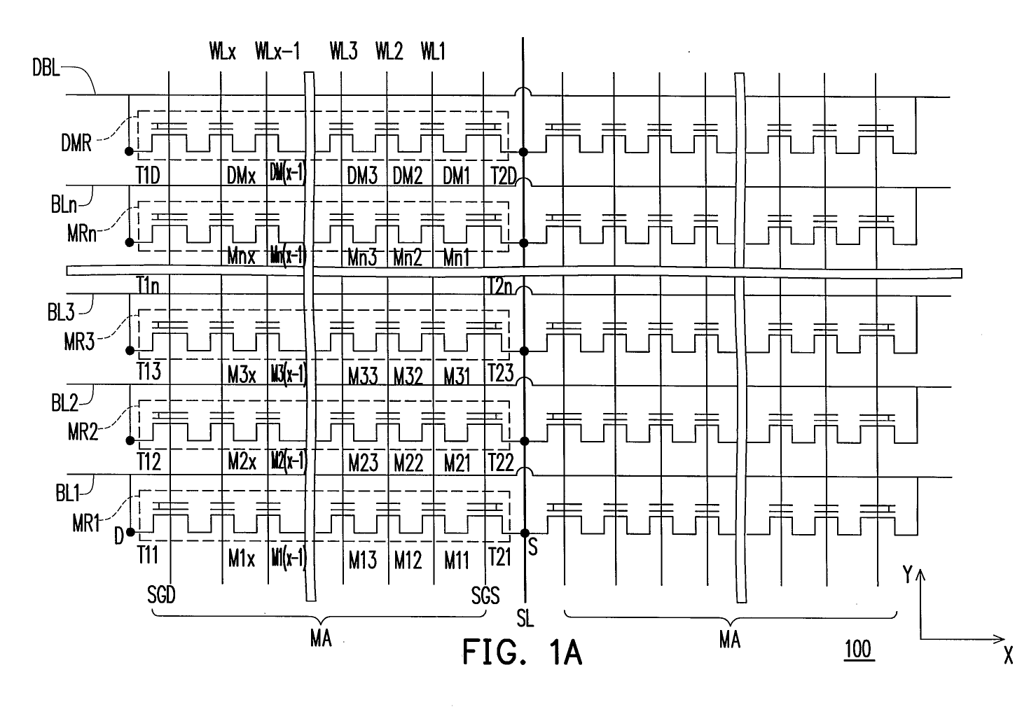

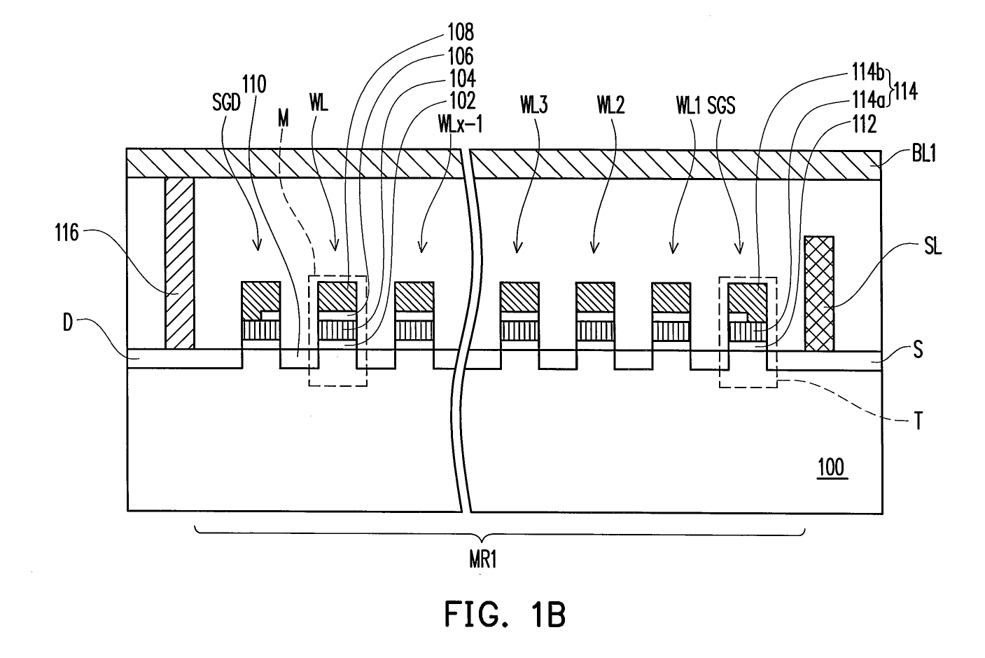

FIG. 1A is a schematic circuit diagram of a NAND type non-volatile memory according to an embodiment of the present invention. FIG. 1B is a cross-sectional view of a NAND type non-volatile memory according to an embodiment of the present invention.

Referring to FIG. 1A and FIG. 1B, the NAND type non-volatile memory provided by the present invention may be composed of a plurality of memory cell arrays MA. The memory cell arrays MA will be described below.

The memory cell arrays MA may be disposed on a substrate 100, wherein the substrate 100 may be a silicon substrate. A device isolation structure (not shown) may be disposed in the substrate 100 to define an active area (not shown). The device isolation structure may be a shallow trench isolation structure or a field oxide layer. The device isolation structure is arranged in parallel in a direction X and extended toward the direction X.

Each of the memory cell arrays MA includes a plurality of word lines WL1˜WLx, two select gate lines SGS and SGD, a plurality of bit lines BL1˜BLn, a dummy bit line DBL, a plurality of drain regions D, a plurality of source regions S, and a source line SL.

The select gate line SGD, the word lines WL1˜WLx, and the select gate line SGS may be disposed in parallel on the substrate 100 and extended toward a direction Y. The select gate lines SGD and SGS may be respectively disposed at both sides of the word lines WL1˜WLx.

The bit lines BL1˜BLn and the dummy bit line DBL may be disposed in parallel on the substrate 100 and extended toward the direction X, wherein the direction X intersects with the direction Y. The intersections of each of the bit lines BL1˜BLn with the select gate line SGD, the word lines WL1˜WLx, and the select gate line SGS are respectively corresponding to a memory cell row MR1˜MRn. The intersections of the dummy bit line DBL with the select gate line SGD, the word lines WL1˜WLx, and the select gate line SGS are corresponding to a dummy memory cell row DMR. The parts of all the word lines WL1˜WLx spanning over the active area are served as a memory cell M11˜Mnx. Memory cell rows MR1˜MRn composed of these memory cells M11˜Mnx are disposed below the bit lines BL1˜BLn. Namely, the intersections of the bit lines BL1˜BLn and the word lines WL1˜WLx are respectively corresponding to the memory cells M11˜Mnx. The intersections of the dummy bit line DBL1 and the word lines WL1˜WLx are corresponding to the dummy memory cell row DMR which is composed of the dummy memory cells DM1˜DMx.

The parts of the two select gate lines SGD and SGS spanning over the active area are respectively served as select units T11˜T1n, T1D, T21˜T2n, and T2D. Namely, the intersections of the bit lines BL1˜BLn, the dummy bit line DBL, and the select gate lines SGD and SGS are respectively corresponding to the select units T11˜T1n, T1D, T21˜T2n, and T2D. Moreover, the select gate line SGD is disposed between the drain regions D and the memory cells M1x˜Mnx and the dummy memory cell DMx, and the select gate line SGS is disposed between the source regions S and the memory cells M11˜Mn1 and the dummy memory cell DM1. The intersections of the bit lines BL1˜BLn, the dummy bit line DBL, and the select gate lines SGD and SGS are respectively corresponding to the select units T11˜T1n, T1D, T21˜T2n, and T2D.

Next, the structures of the memory cell rows MR1˜MRn and the dummy memory cell row DMR will be described. Since the structure of the dummy memory cell row DMR is the same as that of the memory cell rows MR1˜MRn, only the structure of the memory cell row MR1 will be described herein, wherein a memory cell M and a select unit T will be taken as an example. As shown in FIG. 1B, each memory cell M includes a substrate 100, a dielectric layer 102, a charge storage layer 104, an inter-gate dielectric layer 106, a control gate 108, and a doped region 110 in sequence.

The control gate 108 may be disposed on the substrate 100. The control gate 108 may be made of a conductive material, such as doped polysilicon, metal, or metal silicide. Besides, the control gate 108 may be composed of two or more layers of conductive materials.

The charge storage layer 104 may be disposed between the control gate 108 and the substrate 100, and the material of the charge storage layer 104 may be a conductive material (for example, doped polysilicon) or a charge trapping material (for example, silicon nitride).

The dielectric layer 102 may be disposed between the substrate 100 and the charge storage layer 104, and the material thereof may be silicon oxide. The inter-gate dielectric layer 106 may be disposed between the control gate 108 and the charge storage layer 104. The inter-gate dielectric layer 106 may be composed of an oxide/nitride/oxide (ONO) layer. However, the material of the inter-gate dielectric layer 106 may also be silicon oxide, silicon nitride, silicon-oxy-nitride, or silicon oxide/silicon nitride etc.

The doped region 110 may be disposed in the substrate 100 at both sides of the memory cells M. These memory cells M are connected to each other in series through the doped region 110.

The select unit T sequentially includes a dielectric layer 112 and a conductive layer 114 starting from the substrate 100.

The conductive layer 114 may be disposed on the substrate 100 and may be composed of two conductive layers 114a and 114b. The conductive layer 114 may be made of doped polysilicon.

The dielectric layer 112 may be disposed between the conductive layer 114 and the substrate 100. The dielectric layer 112 may be made of silicon oxide.

The drain regions D may be respectively disposed in the substrate 100 at one side of the memory cell rows MR1˜MRn and the dummy memory cell row DMR. These drain regions D may be electrically connected to the bit lines BL1˜BLn and the dummy bit line DBL respectively through a plug 116. The source regions S may be respectively disposed in the substrate 100 at the other side of the memory cell rows MR1˜MRn and the dummy memory cell row DMR.

The source line SL may be disposed on the substrate 100 at the same side of the source regions S of the memory cell rows MR1˜MRn and the dummy memory cell row DMR and extended toward the direction Y, and the source line SL is electrically connected to the source regions S. In the present embodiment, no plug for connecting to an external circuit is disposed on the source line SL; instead, only the dummy memory cell row DMR and the dummy bit line DBL are served as a current path.

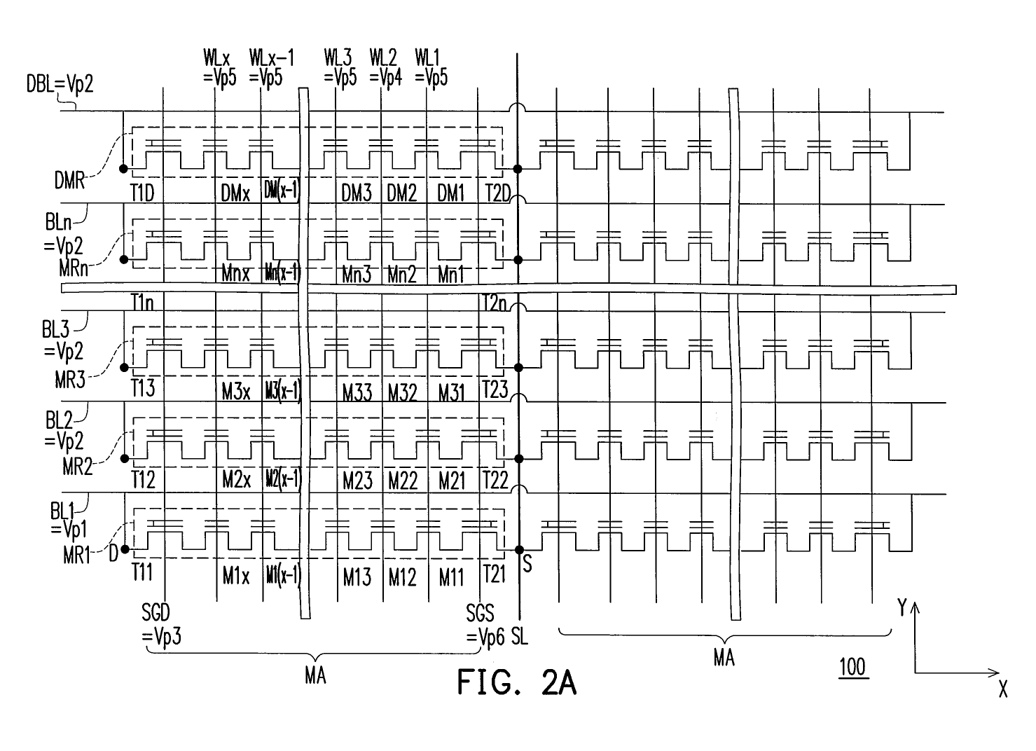

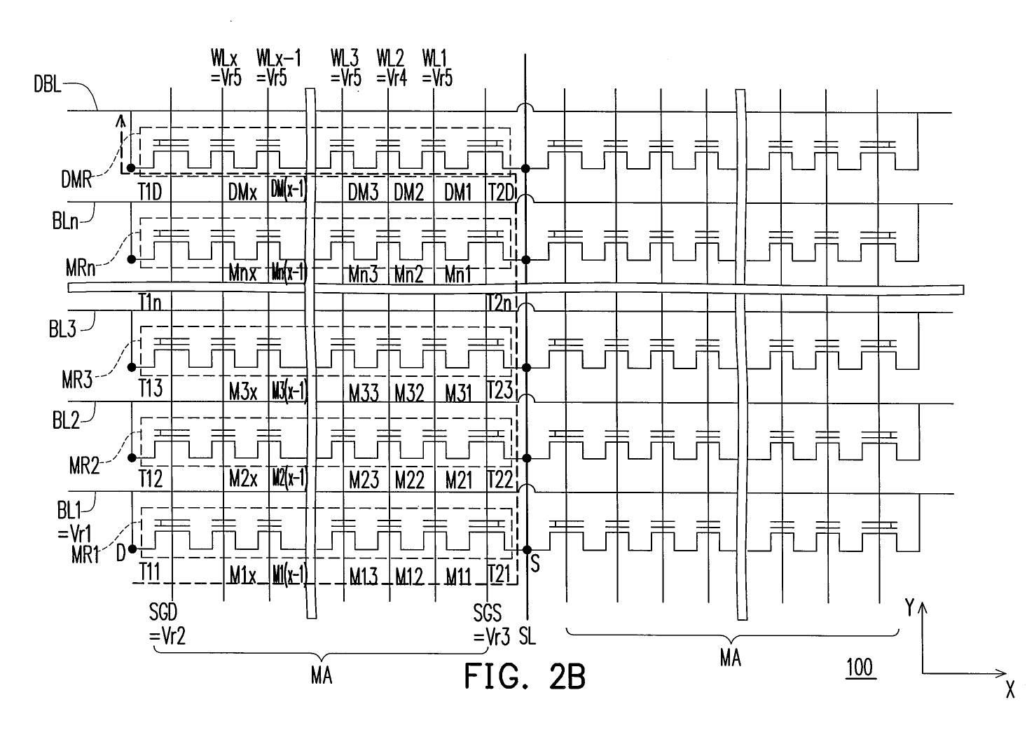

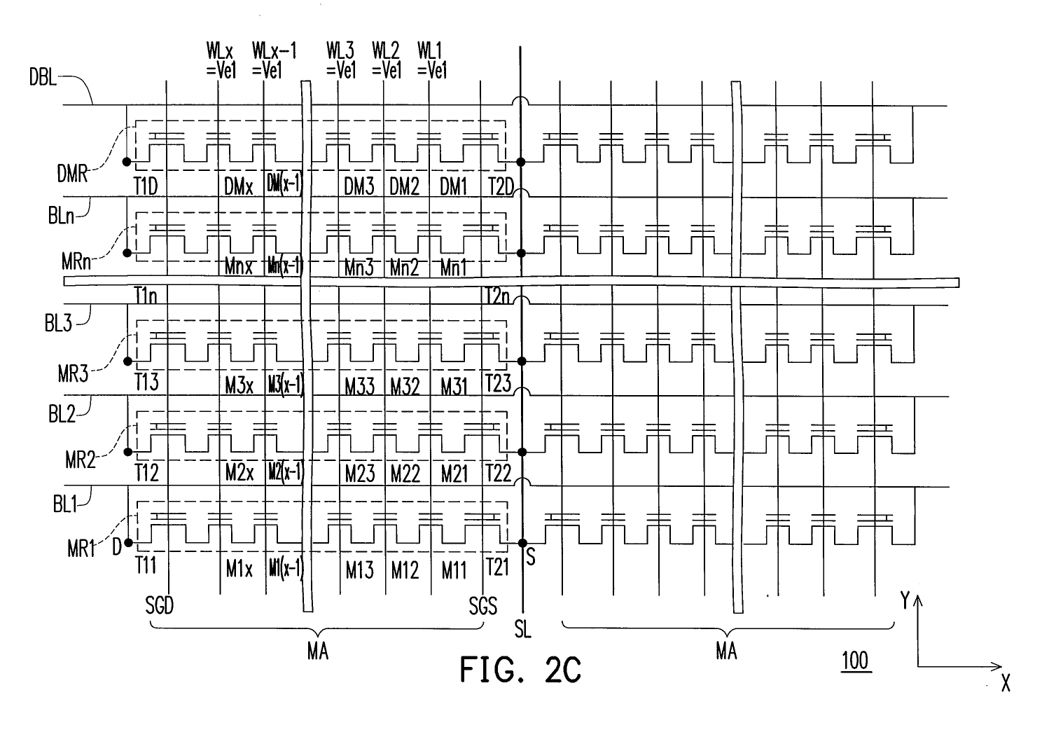

As shown in FIG. 2A, the memory cell arrays MA may be disposed in mirror symmetry in the direction X, and adjacent two memory cell arrays MA share the same drain region D or the same source region S. For example, a memory cell array MA shares the drain region D with an adjacent memory cell array MA at the same side as the select gate line SGD, and the memory cell array MA shares the source region S (and the source line) with an adjacent memory cell array MA at the same side as the select gate line SGS.

In a NAND type non-volatile memory provided by the present invention, additional process for fabricating a source line plug is not required since the dummy memory cell row DMR and the dummy bit line DBL are directly served as a current path for connecting the source line.

In a NAND type non-volatile memory provided by the present invention, only the space of a dummy bit line served as a current path for connecting the source line is required. Since it is not needed to use the space of at least three dummy bit lines for fabricating a source line plug, as in the conventional technique, the present invention reduces the surface area of the NAND type non-volatile memory and increases the device integration thereof.

In a NAND type non-volatile memory provided by the present invention, the select unit in the dummy memory cell row can be used as a circuit for controlling the source line. Accordingly, it is not necessary to fabricate an additional circuit for controlling the source line. As a result, the surface area of the NAND type non-volatile memory is reduced and the device integration thereof is improved.

In a NAND type non-volatile memory provided by the present invention, it is not needed to use the space of at least three dummy bit lines for fabricating the source line plug, as in the conventional technique. Accordingly, the memory array has a regular pattern, and as a result, the process window of a photolithography and etching process is improved.

An operating method for a NAND type non-volatile memory provided by the present invention will be described below, wherein the operating method includes a data programming, a data erasing, and a data reading mode. Only one embodiment of the operating method for a non-volatile memory in the present invention will be described herein. However, the operating method of a non-volatile memory provided by the present invention is not limited to this embodiment. FIG. 2A is a diagram illustrating a programming operation performed to a memory array. FIG. 2B is a diagram illustrating a reading operation performed to a memory array. FIG. 2C is a diagram illustrating an erasing operation performed to all the memory cells. In following description, the memory cell M12 illustrated in FIGS. 2A˜2C will be taken as an example.

Referring to FIG. 2A, when a programming operation is performed to the memory cell M12 in a selected memory cell row MR1, a voltage Vp1 is applied to the bit line BL1 coupled to the memory cell M12, a voltage Vp2 is applied to the non-selected bit lines BL2 and BL3˜BLn and the dummy bit line DBL, a voltage Vp3 is applied to the select gate line SGD, a voltage Vp4 is applied to the word line WL2 coupled to the selected memory cell M12, a voltage Vp5 is applied to the non-selected word lines WL1 and WL3˜WLx, a voltage Vp6 is applied to the select gate line SGS, so as to program the selected memory cell M12 through the channel F-N tunneling effect. The voltage difference between the voltage Vp4 and the voltage Vp1 may incur the F-N tunneling effect. The voltage Vp3 is higher than or equal to the threshold voltage of the select units T11˜T1n and T1D. The voltage Vp2 can prevent the select units T12˜T1n of the non-selected memory cell rows MR2˜MRn and the select unit T1D of the dummy memory cell row DMR from being turned on. The voltage Vp5 is higher than or equal to the threshold voltage of the memory cell. The voltage Vp6 is lower than the threshold voltage of the select units T21˜T2n and T2D.

In the present embodiment, the voltage Vp1 is about 0V, the voltage Vp2 is about 2.4V, the voltage Vp3 is about 2.4V, the voltage Vp4 is about 26V, the voltage Vp5 is about 10V, and the voltage Vp6 is about 0V.

During foregoing programming operation, regarding those non-selected memory cells M22, M32, and Mn2 and the dummy memory cell DM2 which share the word line WL2 with the selected memory cell M12, since a voltage which can prevent the select units T12˜T1n and the select unit T1D from being turned on is applied to the non-selected bit lines BL2˜BLn and the dummy bit line DBL coupled to the non-selected memory cells M22, M32, and Mn2 and the dummy memory cell DM2, the non-selected memory cells M22, M32, and Mn2 and the dummy memory cell DM2 can be prevented from being programmed. Besides, the voltage applied to the non-selected word lines WL1 and WL3˜WLx is only used for opening up the channels of the non-selected memory cells but is not sufficient for incurring the FN tunneling effect. Thereby, the non-selected memory cells are not programmed.

Referring to FIG. 2B, when a reading operation is performed to the selected memory cell M12 in the selected memory cell row MR1, a voltage Vr1 is applied to the bit line BL1 coupled to the selected memory cell M12, a voltage Vr2 is applied to the select gate line SGD, a voltage Vr3 is applied to the select gate line SGS, a voltage Vr4 is applied to the word line WL2 coupled to the selected memory cell M12, a voltage Vr5 is applied to the non-selected word lines WL1 and WL3˜WLx, so as to read the selected memory cell M12, wherein the voltage Vr2 is higher than or equal to the threshold voltage of the select units T11˜T1n and T1D, the voltage Vr3 is higher than or equal to the threshold voltage of the select units T21˜T2n and T2D, and the voltage Vr5 is higher than or equal to the threshold voltage of the memory cell. The source line is grounded through the dummy memory cell row and the dummy bit line DBL.

In the present embodiment, the voltage Vr1 is about 1.2V, the voltage Vr2 is about 5V, the voltage Vr3 is about 5V, the voltage Vr4 is about 0V, and the voltage Vr5 is about 6.5V.

With foregoing voltage applies, the digital information stored in the memory cell M12 can be determined according to the channel current in the memory cell M12.

Next, a method for erasing a NAND type non-volatile memory provided by the present invention will be described below. The erasing of the entire NAND type non-volatile memory will be described herein as an example of the erasing method provided by the present invention.

When an erasing operation is performed to a memory cell array, a voltage Ve1 is applied to all the word lines WL1˜WLx, and a voltage Ve2 is applied to the substrate, so as to erase the memory cells through the channel F-N tunneling effect, wherein the voltage difference between the voltage Ve1 and the voltage Ve2 may incur the F-N tunneling effect.

In the present embodiment, the voltage Ve1 is about 0V, and the voltage Ve2 is about 24V.

The erasing of the entire NAND type non-volatile memory is described above as an example of the erasing method provided by the present invention. However, the erasing operation in the present invention for a NAND type non-volatile memory may also be performed to sections or blocks through the control of the word lines WL1˜WLx.

In foregoing operation method for a NAND type non-volatile memory provided by the present invention, since all the dummy memory cells DM1˜DMx in the dummy memory cell row DMR are not used as memory cells, the threshold voltage of the dummy memory cells DM1˜DMx is very low, and accordingly, the channels below the dummy memory cells DM1˜DMx are always turned on when foregoing operations are performed, so that the source line can be connected to external through the dummy memory cell row and the dummy bit line.

Additionally, the select units T1D and T2D in the dummy memory cell row DMR can be used as a circuit for controlling the source line. Accordingly, additionally circuit for controlling the source line is not to be fabricated.

In overview, in a NAND type non-volatile memory and the operating method thereof provided by the present invention, the dummy memory cell row and the dummy bit line DBL are directly used as a current path for connecting the source line. Accordingly, it is not needed to fabricate the source line plug additionally, and the memory array has a regular pattern so that the process window of the photolithography and etching process can be improved. Moreover, the select unit in the dummy memory cell row can be used as a circuit for controlling the source line. Accordingly, additional circuit for controlling the source line is not required. Furthermore, in the present invention, the space of only one dummy bit line used as a current path for connecting the source line is taken. Accordingly, the surface area of the memory is reduced and the device integration thereof is improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A NAND type non-volatile memory, comprising a plurality of memory cell arrays, wherein each of the memory cell arrays comprises:
a first select gate line, a plurality of word lines, and a second select gate line, disposed on a substrate in parallel and extended toward a first direction;
a plurality of bit lines and a dummy bit line, disposed in parallel on the substrate and extended toward a second direction, wherein the second direction intersects the first direction, the intersections of each of the bit lines with the first select gate line, the word lines, and the second select gate line are corresponding to a memory cell row, and the intersections of the dummy bit line with the first select gate line, the word lines, and the second select gate line are corresponding to a dummy memory cell row;
a plurality of drain regions, respectively disposed in the substrate at a first side of the memory cell rows and the dummy memory cell row, the drain regions being electrically connected to the bit lines and the dummy bit line respectively;
a plurality of source regions, respectively disposed in the substrate at a second side of the memory cell rows and the dummy memory cell row; and
a source line, disposed on the substrate at the second side of the memory cell row, extended toward the second direction, and electrically connected to the source regions, wherein the dummy memory cell row and the dummy bit line are served as a current path for connecting the source line.

2. The NAND type non-volatile memory according to claim 1, wherein the intersection of each of the bit lines and each of the word lines is corresponding to a memory cell.

3. The NAND type non-volatile memory according to claim 1, wherein the intersections of each of the bit lines with the first select gate line and the second select gate line are respectively corresponding to a select unit.

4. The NAND type non-volatile memory according to claim 1, wherein the memory cell arrays are disposed in mirror symmetry along the second direction, and adjacent two of the memory cell arrays share the drain regions or the source regions.

5. An operating method for a NAND type non-volatile memory, suitable for a memory cell array, the memory cell array comprising: a first select gate line, a plurality of word lines, and a second select gate line disposed in parallel on a substrate and extended toward a first direction; a plurality of bit lines and a dummy bit line, disposed in parallel on the substrate and extended toward a second direction, wherein the second direction intersects the first direction, the intersections of each of the bit lines with the first select gate line, the word lines, and the second select gate line are corresponding to a memory cell row, the intersections of the dummy bit line with the first select gate line, the word lines, and the second select gate line are corresponding to a dummy memory cell row; a plurality of drain regions, respectively disposed in the substrate at a first side of the memory cell rows and the dummy memory cell row, the drain regions are electrically connected to the bit lines and the dummy bit line respectively; a plurality of source regions, respectively disposed in the substrate at a second side of the memory cell rows and the dummy memory cell row; and a source line, disposed on the substrate at the second side of the memory cell rows, extended toward the second direction, and electrically connected to the source regions, wherein the dummy memory cell row and the dummy bit line are served as a current path for connecting the source line, the intersection of each of the bit lines and each of the word lines is corresponding to a memory cell, the intersection of each of the bit lines and the first select gate line is respectively corresponding to a first select unit, and the intersection of each of the bit lines and the second select gate line is respectively corresponding to a second select unit, the operating method comprising:
performing a programming operation to a selected memory cell in a selected memory cell row by applying a first voltage to the bit line coupled to the selected memory cell, applying a second voltage to the non-selected bit lines and the dummy bit line, applying a third voltage to the first select gate line, applying a fourth voltage to the word line coupled to the selected memory cell, applying a fifth voltage to the non-selected word lines, and applying a sixth voltage to the second select gate line, so as to program the selected memory cell through channel F-N tunneling effect, wherein the voltage difference between the fourth voltage and the first voltage incurs the F-N tunneling effect, the third voltage is higher than or equal to the threshold voltage of the first select unit, the second voltage prevents the first select unit in the non-selected memory cell rows from being turned on, the fifth voltage is higher than or equal to the threshold voltage of the memory cells, and the sixth voltage is lower than the threshold voltage of the second select unit.

6. The operating method according to claim 5, wherein the first voltage is about 0V, the second voltage is about 2.4V, the third voltage is about 2.4V, the fourth voltage is about 26V, the fifth voltage is about 10V, and the sixth voltage is about 0V.

7. The operating method according to claim 5 further comprising:
performing a reading operation to the selected memory cell in the selected memory cell row by applying a seventh voltage to the bit line coupled to the selected memory cell, applying an eighth voltage to the first select gate line, applying a ninth voltage to the second select gate line, applying a tenth voltage to the word line coupled to the selected memory cell, and applying an eleventh voltage to the non-selected word lines, so as to read the selected memory cell, wherein the eighth voltage is higher than or equal to the threshold voltage of the first select unit, the ninth voltage is higher than or equal to the threshold voltage of the second select unit, the eleventh voltage is higher than or equal to the threshold voltage of the memory cell, and the source line is grounded through the dummy memory cell row and the dummy bit line.

8. The operating method according to claim 7, wherein the seventh voltage is about 1.2V, the eighth voltage is about 5V, the ninth voltage is about 5V, the tenth voltage is about 0V, and the eleventh voltage is about 6.5V.

9. The operating method according to claim 5 further comprising:
performing an erasing operation to the memory cells by applying a twelfth voltage to all the word lines, and applying a thirteenth voltage to the substrate, so as to erase the memory cells through channel F-N tunneling effect, wherein the voltage difference between the twelfth voltage and the thirteenth voltage can incur F-N tunneling effect.

10. The operating method according to claim 9, wherein the twelfth voltage is about 0V, and the thirteenth voltage is about 24V.
